(19) United States
(12) Patent Application Publication
(10) Pub. No.: US 2026/0305395 A1
(43) Pub. Date: Oct. 1, 2026

(54) SEMICONDUCTOR DEVICES AND METHODS OF MANUFACTURING THEREOF

(71) Applicant: Taiwan Semiconductor Manufacturing Company, Ltd., Hsinchu (TW)

(72) Inventor: Kuan-Ting Chou, Hsinchu City (TW)

(73) Assignee: Taiwan Semiconductor Manufacturing Company, Ltd., Hsinchu (TW)

(21) Appl. No.: 19/280,780

(22) Filed: Jul. 25, 2025

Related U.S. Application Data
(60) Provisional application No. 63/781,693, filed on Apr. 1, 2025.

(51) Int. Cl. H01L 23/538; H01L 23/498

(52) U.S. Cl. CPC H10W 70/611; H10W 70/635; H10W 70/65; H10W 70/685; H10W 90/701

(57) ABSTRACT

A semiconductor device may include an interposer to connect a first semiconductor die to a second semiconductor die. The interposer may include a plurality of metallization layers and a plurality of bump structures disposed over a topmost one of the plurality of metallization layers. A first one of the plurality of metallization layers may include a plurality of first interconnect structures, a plurality of second interconnect structures, and a plurality of third interconnect structures. The plurality of first interconnect structures may carry a first supply voltage. The plurality of second interconnect structures may carry a second supply voltage. The plurality of third interconnect structures may each be as a signal line. Each of the plurality of bump structures may be formed directly above a pair of a corresponding one of the plurality of first interconnect structures and a corresponding one of the plurality of second interconnect structures.

### CROSS-REFERENCE TO RELATED APPLICATION

This application claims the benefit of and priority to U.S. Provisional Application No. 63/781,693, filed Apr. 1, 2025, titled “UCIe Channel PDN solution in CoWoS-L Active LSI,” which is incorporated herein by reference in its entirety.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example semiconductor device, in accordance with some embodiments.

FIG. 2 illustrates a schematic diagram of an example of the interposer shown FIG. 1, in accordance with some embodiments.

FIG. 3 illustrates a schematic diagram of an example of the interposer shown FIG. 2, in accordance with some embodiments.

FIG. 4 illustrates a schematic diagram of an example of the interposer shown FIG. 2, in accordance with some embodiments.

FIG. 5 illustrates a schematic diagram of an alternative example of the interposer shown FIG. 2, in accordance with some embodiments.

FIG. 6 illustrates a schematic diagram of an alternative example of the interposer shown FIG. 2, in accordance with some embodiments.

FIG. 7 illustrates a schematic diagram of an alternative example of the interposer shown FIG. 2, in accordance with some embodiments.

FIG. 8 illustrates schematic diagrams of an alternative example of the interposer shown FIG. 2, in accordance with some embodiments.

FIG. 9 illustrates a schematic diagram of a portion of the interposer shown in FIG. 8, in accordance with some embodiments.

FIG. 10 illustrates a schematic diagram of an alternative example of the interposer shown FIG. 2, in accordance with some embodiments.

FIG. 11 illustrates a schematic diagram of an example of a semiconductor device, in accordance with some embodiments.

FIG. 12 includes a flowchart of a method, in accordance with some embodiments.

FIGS. 13 to 16 respectively illustrate various example packaged semiconductor devices including the disclosed redistribution structure, in accordance with some embodiments.

FIG. 17 illustrates a flowchart of an example method of manufacturing a semiconductor device, in accordance with some embodiments.

FIG. 18 illustrates a block diagram of an example system of generating an IC layout design, in accordance with some embodiments.

FIG. 19 illustrates a block diagram of an example IC manufacturing system, and an example IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As semiconductor systems continue to scale in complexity and bandwidth, high-speed interconnect technologies such as UCIe and packaging platforms like CoWoS-L introduce new challenges in maintaining reliable power and signal integrity. In CoWoS-L Active LSI systems, the interposer channel plays a central role in delivering power and transmitting data between dies. However, limitations in prior designs-insufficient ground width leading to far- and near-end crosstalk, fixed cluster pitch imposing trade-offs between signal and ground allocation, and uneven ground distribution contributing to IR drop-hindered performance. In addition, layouts often require additional routing to connect each bump to its associated power or ground track, increasing parasitic impedance and design complexity. Accordingly, there is a need for improved layout and interconnect strategies that can reduce IR drop and signal interference while supporting high-density UCIe transmission in CoWoS-L environments.

The present application provides techniques for addressing issues related to IR drop, signal interference, and layout inefficiencies in interposer designs. According to the present disclosure, in some embodiments, a semiconductor device may include an interposer configured to connect a first semiconductor die to a second semiconductor die. The interposer may include a plurality of metallization layers, with one metallization layer including a plurality of first interconnect structures configured to carry a first supply voltage (e.g., VDD), a plurality of second interconnect structures configured to carry a second supply voltage (e.g., VSS), and a plurality of third interconnect structures each configured as a signal line. A plurality of bump structures may be disposed above the metallization layer such that each bump structure is vertically aligned above and laterally between a pair of corresponding first and second interconnect structures. This configuration enables a shorter and more direct connection from the bump to the power/ground (P/G) tracks, reducing routing complexity and parasitic impedance. Additionally, by prohibiting signal/ground (S/G) lines in the space between each bump and its underlying P/G pair, the design enhances signal isolation and mitigates crosstalk. These features, combined with balanced and uniform TSV placement under the bump columns, contribute to improved IR drop performance and parasitic impedance reduction, enabling low-power UCIe channel operation and ensuring high-speed, high-reliability inter-die communication in CoWoS-L Active LSI systems.

The figures and description below are provided for purposes of illustration and are not intended to limit the scope of the present disclosure. The figures may be simplified for clarity and may omit certain elements or features for ease of explanation. Components shown in a given arrangement or configuration may be implemented in other suitable ways without departing from scope and sprit of the present disclosure.

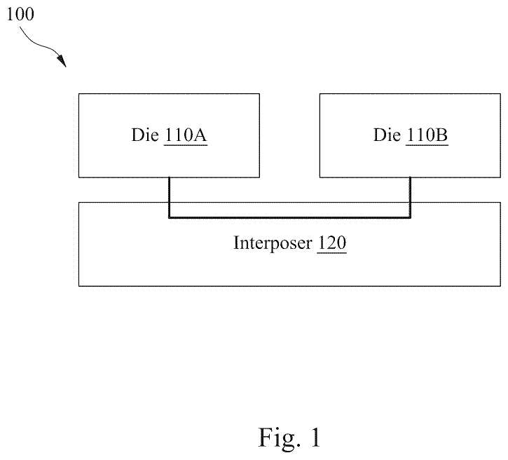

FIG. 1 illustrates a block diagram of an example semiconductor device 100, in accordance with some embodiments. The semiconductor device 100 includes a semiconductor die 110A, a semiconductor die 110B, and an interposer 120. The semiconductor device 100 may be or include any type of integrated system including but not limited to, multiple semiconductor dies (e.g., the dies 110A, 110B), memory dies, interface dies, chiplets configured for high-bandwidth communication, etc. In some examples, the semiconductor device 100 may include power distribution structures, signal interconnects, and vertical interconnects such as through-silicon vias (TSVs), bump structures, or other routing features arranged to support efficient power and signal delivery across the system. In some implementations, the semiconductor device 100 may be compatible with advanced packaging platforms such as CoWoS-L and may support UCIe-based chiplet communication.

The dies 110A and 110B may each be or include any type of semiconductor die configured to perform various digital, analog, or mixed-signal functions, such as to perform processing, communication, memory, or logic functions. In some examples, the dies 110A and 110B may include processor dies, memory dies, input/output (I/O) interface dies, or chiplets implementing specialized functions. Each of the dies 110A and 110B may include front-end-of-line (FEOL) circuitry such as transistors, logic gates, and memory cells, as well as back-end-of-line (BEOL) interconnect structures for signal and power routing. The dies 110A and 110B may be configured to communicate with each other through the interposer 120. The dies 110A and 110B may be bonded to the interposer 120 using bump structures, micro-bumps, or other vertical interconnect techniques. In some implementations, one or both of the dies 110A and 110B may be configured for high-speed communication protocols such as UCIe. While FIG. 1 shows two dies for illustrative clarity, more than two dies may be included in other examples.

The interposer 120 may be or include a semiconductor, glass, or organic interposer structure configured to electrically and mechanically couple the die 110A and the die 110B. For example, the interposer 120 may be configured to transmit signals between the die 110A and the die 110B. The interposer 120 may include multiple metallization layers for routing power, ground, and high-speed signal paths between the dies. In some implementations, the interposer 120 may include features such as TSVs, redistribution layers (RDLs), and bump structures for vertical connections to the dies and to an underlying substrate. In some examples, the interposer 120 may include one or more components configured for fine-pitch signal routing and power distribution to meet the demands of high-bandwidth chiplet communication, such as UCIe. As discussed herein, the interposer 120 may be configured to incorporate CoWoS-L technology and layout strategies for minimizing IR drop and cross talk, such as uniform P/G track placement and optimized TSV distribution. In some implementations, the interposer 120 may be or include a local silicon interconnect (LSI) structure, such as a passive or active silicon interconnect die used to provide high-density routing and vertical connectivity between semiconductor dies (e.g., the dies 110A, 110B).

As shown in FIG. 1, the interposer 120 may be configured to connect the first die 110A to the second die 110B. In some examples, the interposer 120 may include a plurality of metallization layers and a plurality of bump structures disposed over a topmost one of the metallization layers. A first one of the metallization layers may include a plurality of first interconnect structures configured to carry a first supply voltage (e.g., VDD), a plurality of second interconnect structures configured to carry a second supply voltage (e.g., VSS), and a plurality of third interconnect structures each configured as a signal line. Each of the bump structures may be formed vertically above and laterally between a pair of a corresponding one of the first interconnect structures and a corresponding one of the second interconnect structures. In some embodiments, the semiconductor device 100 may include a substrate bonded to a bottom side of the interposer 120.

The interposer 120 may provide several architectural advantages for advanced packaging systems, including both active and passive LSI implementations. For example, the interposer 120 may support a parasitic impedance reduction solution for the channel model and TSV placement by using the topmost metallization layer routing. Such configurations may enable high-bandwidth communication (e.g., up to 10.5 Tbps/mm for 32 Gb/s by 64 UCIe channels) while supporting reduced power consumption (e.g., 0.07 pJ/bit) for transceivers in Active LSI. In some examples, the interposer 120 may include various routing P/G track TSV placement to optimize power distribution network (PDN) performance. This layout may maintain uniform P/G alignment across bump columns to reduce IR drop and support improved PDN impedance characteristics, while ensuring that the routing plan does not significantly impact signal integrity (SI), thereby contributing to robust and scalable system integration.

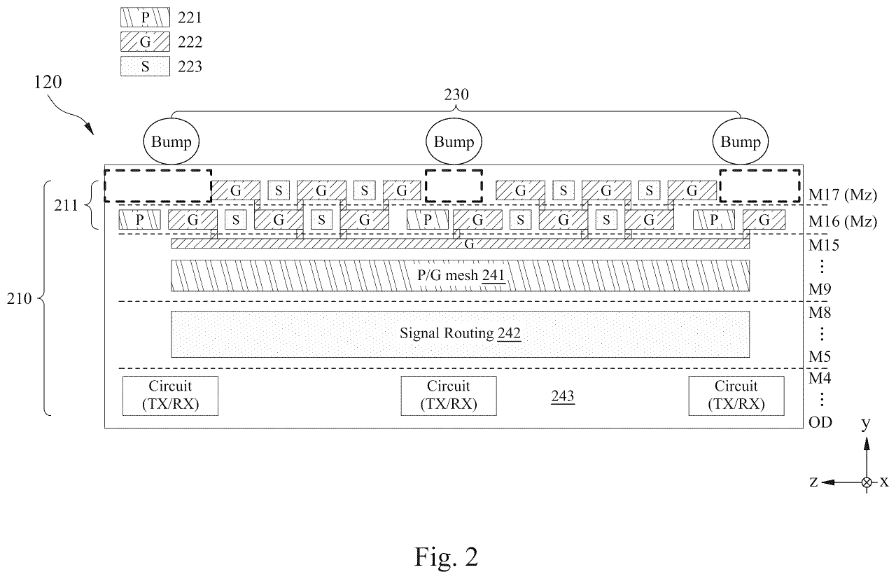

FIG. 2 illustrates a schematic diagram of an example of the interposer 120, in accordance with some embodiments. The interposer 120 may include a plurality of metallization layers 210 and a plurality of bump structures 230. The interposer 120 may be configured to connect the die 110A to the die 110B through the bump structures 230. For example, the first die 110A and the die 110B may be disposed above and bonded to the interposer 120. In some embodiments, first one or more of the bump structures 230 may be connected to (e.g., bonded to) the die 110A, while second one or more of the bump structures 230 may be connected to (e.g., bonded to) the die 110B.

The plurality of metallization layers 210 may be or include patterned metal layers and intervening dielectric layers formed in a stack to provide horizontal and vertical routing for signals, power, and ground. Each of the metallization layers 210 may include one or more interconnect structures such as power lines, ground lines, and signal lines. Each of the metallization layers 210 may include via structures connecting different layers within the stack. In some examples, uppermost layers (e.g., a first metallization layer 211; M17, M16) in the metallization stack may be implemented using thick metal (e.g., 2-Mz) to reduce resistance and support high-current power delivery. The metallization layers 210 may be formed using materials such as copper or aluminum for the conductive features, and silicon dioxide or low-k dielectrics for insulation.

In some embodiments, the first metallization layer 211 may be or include one or more topmost layers of the metallization layers 210. For example, the first metallization layer 211 may be the two topmost layers (e.g., 2-Mz; M16 and M17 as shown in FIG. 2) The first metallization layer 211 may include a plurality of first interconnect structures 221. The first interconnect structures may be configured to carry a first supply voltage (e.g., VDD). The first metallization layer 211 may include a plurality of second interconnect structures 222. The second interconnect structures 222 may be configured to carry a second supply voltage (e.g., VSS). The first metallization layer 211 may include and a plurality of third interconnect structures 223. Each of the third interconnect structures 223 may be configured as a signal line. In some embodiments, the first interconnect structures 221, the second interconnect structures 222, and the third interconnect structures 223 may be disposed in a same metallization layer (e.g., the first metallization layer 211).

The plurality of bump structures 230 may be or include conductive elements configured to provide electrical and mechanical connections between the interposer 120 and one or more semiconductor dies (e.g., the dies 110A, 110B). In some embodiments, each bump structure 230 may be formed from solder, copper pillars, or other conductive materials for fine-pitch bonding and high-density integration. The bump structures 230 may be arranged in a grid or array pattern across the top surface of the interposer 120 and may serve as vertical interconnects for delivering power, ground, and signals to and from the dies mounted on the interposer 120. In some examples, the bump structures 230 may be formed above selected interconnect structures within the metallization layers 210, such as power/ground line pairs or signal lines, to enable optimized current delivery and minimized parasitic impedance, as discussed herein.

In some embodiments, the bump structures 230 may be disposed over a topmost one (e.g., the first metallization layer 211, M17) of the metallization layers 210. For example, each of the bump structures 230 may be formed vertically above the first metallization layer 211. In some embodiments, each of the bump structures 230 may be formed directly above a pair of a corresponding one of the first interconnect structures 221 and a corresponding one of the second interconnect structures 222. For example, as shown in FIG. 2, each of the bump structures 230 may be disposed directly above the corresponding P/G pair. In some embodiments, each of the bump structures 230 may be disposed laterally between the pair of the corresponding first interconnect structure 221 and the corresponding second interconnect structure 222. For example, the bump structure 230 may be formed on the first metallization layer 211, laterally spaced with a pitch of 38.88 μm. By arranging each of the bump structures 230 above a corresponding pair of P/G tracks, alignment between vertical and lateral current paths can be improved, and power delivery is simplified. Furthermore, this allows for selective connection of each of the bump structures 230 to only one of the P or G tracks in the P/G pair, which can reduce routing complexity and shorten the interconnect length, further reducing parasitic impedance and improving overall PDN efficiency. In some examples, the second and third interconnect structures 222, 223 may be restricted or forbidden from the space between the bump and the P/G pair, thereby reducing the potential for crosstalk and maintaining cleaner isolation between power and signal domains.

In some examples, the interposer 120 may include one or more dummy bump structures disposed between adjacent bump structures (e.g., the bump structures 230). These dummy bumps may not be electrically connected but may be used to maintain mechanical uniformity and thermal balance across the surface of the interposer 120. Incorporating dummy bumps can mitigate stress concentration, improve planarity during bonding, and enhance thermal spreading across the interposer 120, contributing to more reliable device operation and assembly yield, for example, in applications with asymmetric bump loading or temperature gradients.

In the example illustrated in FIG. 2, the interposer 120 is shown to include various features beneath the first metallization layer 211. For example, the interposer 120 may include a P/G mesh region 241 spanning one or more metallization layers (e.g., M9 through M15). The P/G mesh region 241 may be configured to distribute the first and second supply voltages (e.g., VDD, VSS) laterally across the interposer 120. In some implementations, the P/G mesh region 241 may be formed using a repeating pattern of horizontal and vertical interconnects to ensure even voltage distribution and reduce IR drop. In some examples, the P/G mesh region 241 may be electrically coupled to the first and/or second interconnect structures 221, 222 in the first metallization layer 211. In some examples, the P/G mesh region 241 may be electrically connected vertically to underlying structures, such as TSVs or adapter layers.

In some examples, the interposer 120 may include a signal routing region 242 that spans one or more metallization layers (e.g., M5 through M8). The signal routing region 242 may include interconnect structures configured to route input/output signals, control signals, or data paths between different components of the semiconductor device (e.g., between the dies 110A and 110B). In some embodiments, the signal routing region 242 may be physically separated from the P/G mesh region 241 by one or more dielectric layers and may be optimized for signal integrity (e.g., through shielding or controller impedance routing).

In some examples, the interposer 120 may include a circuit region 243. The circuit region 243 may be formed using active or passive device layers depending on whether the interposer 120 is part of an active or passive LSI. While FIG. 2 illustrates the interposer 120 as an active LSI in which the circuit region 243 includes circuit components such as a transmitter (TX) and a receiver (RX), the interposer 120 may include the circuit region 243 for a passive LSI. In some implementations, the circuit region 243 may include logic or interface components that drive or terminate the signals routed through the signal routing region 242. The interposer 120 may include TSVs and other vertical interconnects that provide electrical coupling between the circuit region 243 and upper layers (e.g., the signal routing region 242, the P/G mesh region 241, the first metallization layer 211, etc.). For example, the interposer 120 may include TSVs under the circuit region 243.

In some implementations, although not shown, the interposer 120 may include a configurable routing region (e.g., disposed between M15 and M16). For example, the configurable routing region may include a programmable routing switch or fuse, etc. This can allow for post-fabrication reassignment of bump-to-interconnect connections, enabling on-die customization and/or adaptive routing for yield recovery. For instance, if a defect is defected in a specific signal or power path, an alternative path may be activated through programmable switches. This feature may improve overall manufacturing yield and allow late-stage PDN/SI optimization.

Although not shown, the interposer 120 may be bonded to a substrate, in some embodiments. The substrate may be disposed below the interposer 120 and bonded to the interposer 120 (e.g., a bottommost layer of the interposer 120). Although FIG. 2 illustrates examples in which the interposer 120 includes up to seventeen metallization layers (e.g., up to the M17 layer), the number of metallization layers is not limited thereto. In other embodiments, the interposer 120 may include more or fewer layers (e.g., eighteen or more, or sixteen or fewer), to satisfy various design constraints or process capabilities.

In some embodiments, the interposer 120 may include a plurality of via structures, as described herein. For example, the interposer 120 may include a via structure configured to connect a corresponding one of the bump structures 230 to a corresponding one of the first interconnect structures 221 (or the second interconnect structures 222, the third interconnect structures 223). For example, the interposer 120 may include a first via structure and a second via structure each configured to connect a corresponding one of the bump structures 230 to a corresponding one of the third interconnect structures 223. In the figures and description below, non-limiting examples of the via structures are discussed.

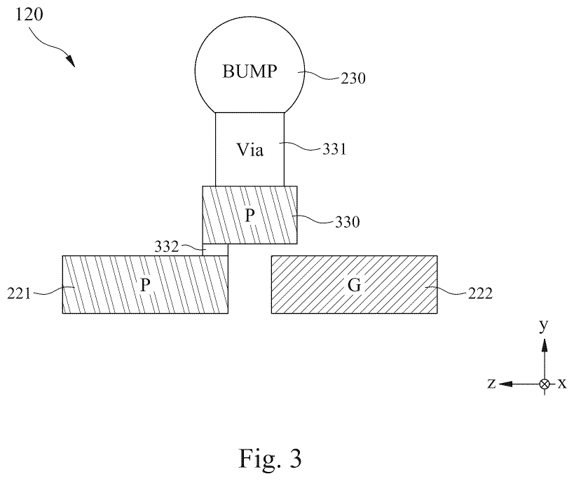

FIG. 3 illustrates a schematic diagram of an example of the interposer 120, in accordance with some embodiments. Specifically, shown in FIG. 3 is a portion of the first metallization layer 211 and the bump structures 230. In the example of FIG. 3, the interposer 120 additionally includes a connection metal 330, a first via structure 331, and a second via structure 332.

The first via structure 331 may be configured to connect the bump structure 230 to the connection metal 330. As shown, the first via structure 331 may vertically extend to electrically couple the bump structure 230 to the connection metal 330. In some implementations, the bump structure 230 may be configured to serve as a connection for power (or ground), and the connection metal 330 may be connected to the first interconnect structure 221 as shown (or connected to the second interconnect structure 222). That is, the configuration of the portion shown in FIG. 3 may be determined based on the attributes of the bump structure 230 (e.g., power or ground). In some embodiments, the second via structure 332 may vertically extend to electrically couple the connection metal 330 to the first interconnect structure 221 (or to the second interconnect structure 222). The second via structure 332 may be disposed vertically beneath the first via structure 331. Although not shown, the interposer 120 of FIG. 3 may be configured such that the bump structure 230 may be configured to serve as a connection for ground, and the connection metal 330 may be connected to the second interconnect structure 221 through the second via structure 332.

In some embodiments, each of the bump structures 230 may be connected to both a power track (e.g., the first interconnect structure 221) and a signal line (e.g., the third interconnect structure 223) through separate via structures disposed in vertically adjacent but non-overlapping metallization layers. For example, the power via may extend from the bump to M16 while the signal via may extend from the bump to M15 or a lower layer. This may physically separate power and signal paths within the vertical interconnect stack, reducing capacitive coupling and improving overall signal integrity, particularly in high-speed communication applications. Such a structure may be especially beneficial in CoWoS-L designs where signal isolation is critical under dense UCIe routing environments.

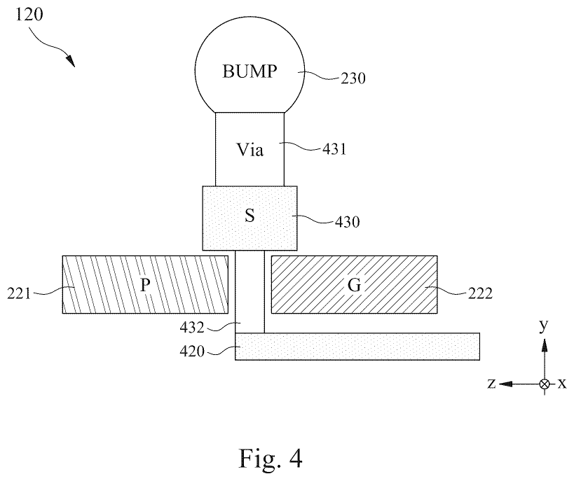

FIG. 4 illustrates a schematic diagram of an example of the interposer 120, in accordance with some embodiments. Specifically, shown in FIG. 4 is a portion of the first metallization layer 211 and the bump structures 230. In the example of FIG. 4, the interposer 120 additionally includes a connection metal 430, a first via structure 431, a second via structure 432, and a fourth interconnect structure 420. As discussed herein, in some embodiments, each of the bump structures 230 may be coupled to a corresponding one of the third interconnect structures 223 (not shown) through one or more via structures (e.g., the first via structure 431, the second via structure 432) and one or more interconnect structures (e.g., the fourth interconnect structure 420).

The first via structure 431 may be configured to connect the bump structure 230 to the connection metal 430. As shown, the first via structure 431 may vertically extend to electrically couple the bump structure 230 to the connection metal 430. In some implementations, the bump structure 230 may be configured to serve as a connection for signal, and the connection metal 430 may be connected to the third interconnect structure 223 (not shown). That is, the configuration of the portion shown in FIG. 4 may be determined based on the attributes of the bump structure 230 (e.g., P/G or signal). In some embodiments, the second via structure 432 may vertically extend to electrically couple the connection metal 430 to the fourth interconnect structure 420. The second via structure 432 may be disposed vertically beneath the first via structure 431. In some embodiments, as shown, the second via structure 432 may be laterally interposed between the pair of the first interconnect structure 221 and the second interconnect structure 222. In some embodiments, the first via structure 431 may have a first width and the second via structure 432 may have a second width, and the first width may be greater than the second width. The second via structure 432 laterally interposed between the pair of the first interconnect structure 221 and the second interconnect structure 222 can enhance area efficiency by utilizing the space between adjacent power and ground tracks. This allows routing flexibility for connecting upper-layer metals (e.g., M17) to underlying layers, helping to reduce vertical congestion while maintaining tight pitch and low parasitic impedance in the power delivery network.

The fourth interconnect structure 320 may be configured to connect the second via structure 432 to the third interconnect structure 223 (not shown). In some embodiments, the first interconnect structure 221, the second interconnect structure 222, and the third interconnect structure 223 may extend along a first lateral direction (e.g., the x-direction as shown in FIG. 2). The fourth interconnect structure 420 may extend along a second lateral direction (e.g., the z-direction) perpendicular to the first lateral direction. In some embodiments, the fourth interconnect structure 420 may be disposed in a second metallization layer. The second metallization layer may be disposed below the first metallization layer 211 shown in FIG. 2. In some embodiments, the second metallization layer may be a lower portion of the first metallization layer 211 (e.g., between the first metallization layer 211 and M15, etc.) shown in FIG. 2.

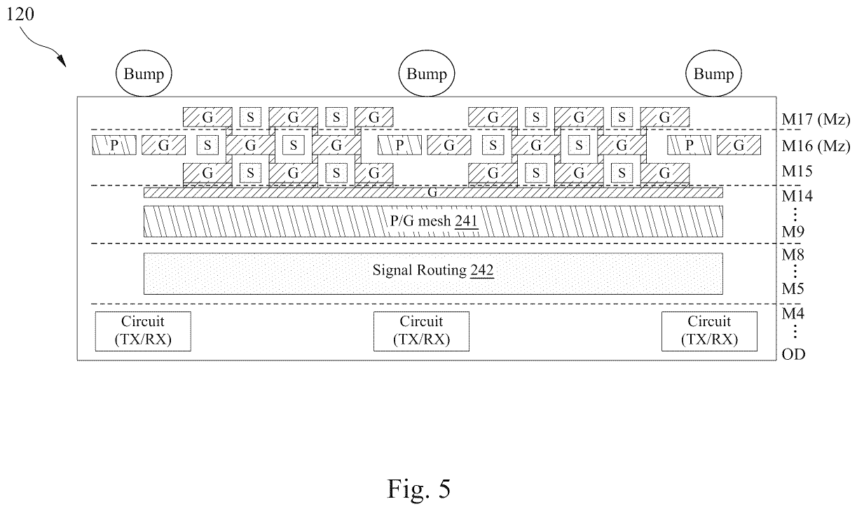

FIG. 5 illustrates a schematic diagram of an alternative example of the interposer 120, in accordance with some embodiments. The interposer 120 of FIG. 5 may be similar to the configuration shown in FIG. 2, including the metallization layers 210, the bump structures 230, the signal routing region 242 (e.g., M5-M8), and the circuit region 243. The interposer 120 may alternatively include the metallization layer M15 configured to include additional signal and ground lines (e.g., rather than being part of the P/G mesh region 241 in FIG. 2). Accordingly, the P/G mesh region 241 may span a reduced range of layers (e.g., from M9 through M14, instead of M9 through M15 as shown in FIG.) 2. This allows for three or more layers (e.g., M15-M17) to form the upper routing stack, and helps reduce power routing congestion while providing additional flexibility in signal or mixed S/G routing near the top of the metallization stack. By redistributing P/G resources and expanding the utility of M15, this configuration offers improved area efficiency while maintaining electrical performance.

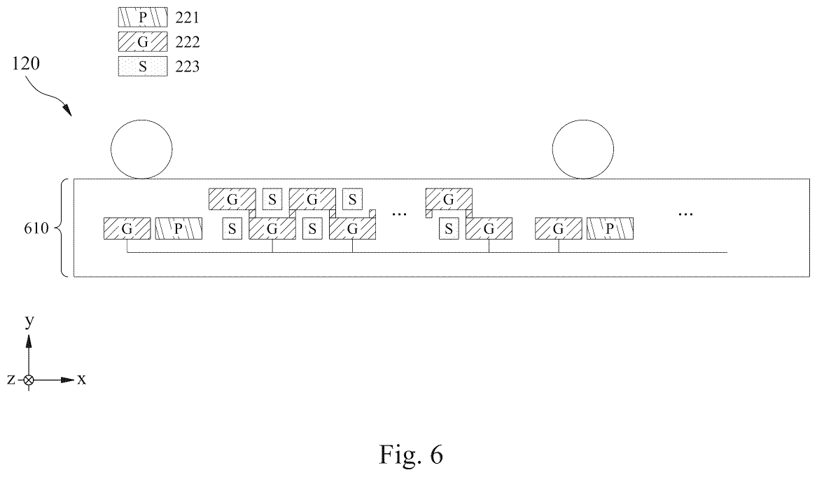

FIG. 6 illustrates a schematic diagram of an alternative example of the interposer 120, in accordance with some embodiments. The interposer 120 of FIG. 6 may be similar to the configuration shown in FIG. 2. In the example of FIG. 6, the interposer 120 may include an interconnect region 610, which may be or be part of the metallization layers 211 described with respect to FIG. 2. For example, the interconnect region 610 may include the first, second, and third interconnect structures 221, 222, 223 and various via structures discussed with respect to FIG. 2 to FIG. 5. The interconnect region 610 may include any number of metallization layers (e.g., one layer, two-Mz layer similar to the interposer 120 of FIG. 2, or more layers).

As shown in FIG. 6, the first, second, and third interconnect structures 221, 222, 223 may be arranged in a layout that enables flexible routing and selective bump connectivity. In some embodiments, each of the bump structures 230 may be disposed above or in proximity to selected one or more interconnect structures (e.g., one of the first, second, and third interconnect structures 221, 222, 223), and may be electrically coupled thereto. For instance, a bump may connect to a power line (e.g., the first interconnect structure 221), a ground line (e.g., the second interconnect structure 222), or a signal line (e.g., the third interconnect structure 223).

In some examples, the first, second, and third interconnect structures 221, 222, 223 may include repeating or partially repeating patterns of interconnect types, as illustrated by alternating arrangements of the first, second, and third interconnect structures 221, 222, 223. This enables localized flexibility for connecting power, ground, and signal lines through the bump structures 230, and may be adapted based on signal integrity, current demand, or physical design constraints. In certain embodiments, the first, second, and third interconnect structures 221, 222, 223 may be connected to underlying routing or mesh layers (e.g., the P/G mesh region 241 or signal routing region 242 in FIG. 2) through one or more via structures or adapter routing layers.

Although FIG. 6 shows a specific arrangement of the first, second, and third interconnect structures 221, 222, 223, the configuration is not limited thereto. In some implementations, the number, pitch, and order of these interconnect lines may be adjusted to accommodate various die layouts, performance or fabrication constraints.

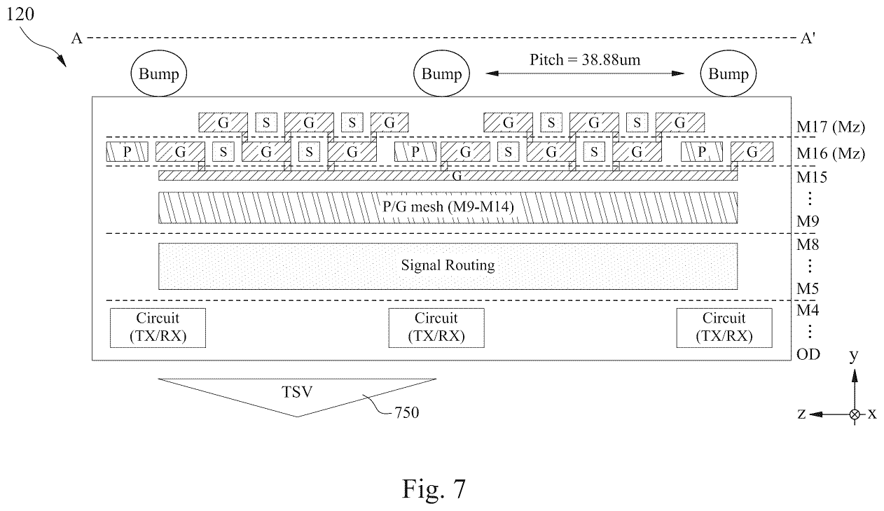

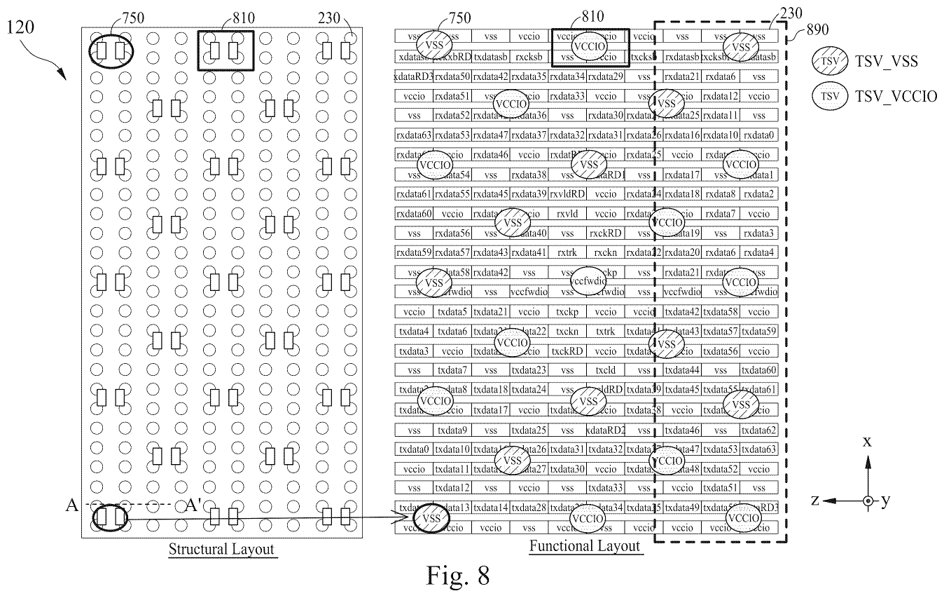

FIG. 7 illustrates a schematic diagram of an alternative example of the interposer 120, in accordance with some embodiments. As shown, the interposer 120 may additionally include one or more through-silicon vias (TSV) 750. The TSV 750 may extend vertically through the interposer 120 to provide electrical connectivity between upper metallization layers (e.g., the metallization layers 210) and a substrate (not shown). In some embodiments, each TSV 750 may be configured to transmit a supply voltage (e.g., VSS, VCCIO), a ground signal, or a data signal. The TSV 750 may be disposed beneath various functional regions of the interposer 120, including the circuit region 243, the signal routing region 242, and the P/G mesh region 241, and may serve as vertical interconnects coupling these regions to the substrate. In some examples, the substrate may be disposed below the interposer 120 and may provide global power delivery and signal routing support for the overall semiconductor device. By integrating TSV 750 within the interposer 120, vertical connections may be established between top-mounted dies (e.g., the dies 110A, 110B) and the substrate to facilitate efficient power distribution and signaling. In some embodiments, FIG. 7 corresponds to a cross-sectional view taken along the line AA′ shown in FIG. 8. As discussed below, the interposer 120 may include a plurality of the TSVs 750 with various arrangement and/or configuration.

FIG. 8 illustrates schematic diagrams of an alternative example of the interposer 120, in accordance with some embodiments. More specifically, shown in FIG. 8 are a top, structural layout (left) and a top, functional layout (right) of the interposer 120 including the TSVs 750. In some embodiments, FIG. 8 shows planar layouts of the interposer 120 shown in FIG. 7, while FIG. 7 shows a vertical structure of the interposer 120 including the TSVs 750 extending downward to a substrate.

Referring to the structural layout, in some embodiments, the interposer 120 may include a plurality of cluster areas 810 arranged in a grid-like pattern. Each cluster area 810 may correspond to a region configured to support an individual die tile or logic macro, such as a transceiver block, or processing unit. In some embodiments, as illustrated, each cluster area 810 may be bordered, surrounded, or formed by four or more bump structures 230. The TSVs 750 within each cluster area 810 provide vertical connectivity between the substrate and the metallization layers 210 of the interposer 120, and may be configured to deliver supply voltages (e.g., VDD, VSS), reference voltages (e.g., VCCIO), or other signals within each cluster area 810. The bump structures 230 within each cluster area 810 may be configured to connect to corresponding one or more semiconductor dies (e.g., the dies 110A, 110B), such that the TSVs 750 is connected to the one or more semiconductor dies (e.g., the dies 110A, 110B). Although the structural layout shows four bump structures per cluster, the TSVs 750 may not be directly coupled to all four bump structures.

In some embodiments, the TSVs 750 may be arranged to maintain a 1:1 power-to-ground (P/G) ratio, which provides symmetric current return paths and enhances power integrity. For example, within each group of the TSVs 750 within each cluster area 810, two may carry power and two may carry ground. This arrangement also reduces the loop inductance for transient currents and limits noise coupling across the die connected to the interposer 120.

As shown in the functional layout, an example distribution of power and signal zones is depicted with each block corresponding to a bump and its voltage or data. The functional layout may represent a higher-level abstraction of the interposer 120, showing the physical regions allocated to power delivery, ground distribution, and signal routing. In some examples, the functional layout may reflect the use of a modular or column-based architecture in which power, ground, and signal resources are spatially distributed in a regular pattern. As illustrated, the P/G areas may be arranged in alternating rows or columns to align with the cluster areas 810 and their corresponding TSVs 750, ensuring localized power integrity across the interposer surface. The signal regions may be interleaved with the P/G areas and may be configured to support UCIe channel routing or other high-speed interconnections. Such an arrangement facilitates uniform electrical behavior, reduces coupling noise between adjacent regions, and allows for predictable parasitic impedance characteristics across the die area. For example, the TSVs 750 may be evenly distributed across the interposer 120 in a staggered arrangement, as shown. This can enhance layout flexibility and improve current spreading. In some embodiments, the number of TSVs 750 coupled to VSS (e.g., ground) may be selected to exceed or match the number of the TSVs 750 coupled to VDD to ensure robust return paths and noise suppression. In some examples, the functional layout may support efficient placement of adapters or routing layers (e.g., RV/AP) that connect the metallization stack to the TSVs 750 or the bump structures 230, further optimizing signal integrity and PDN performance.

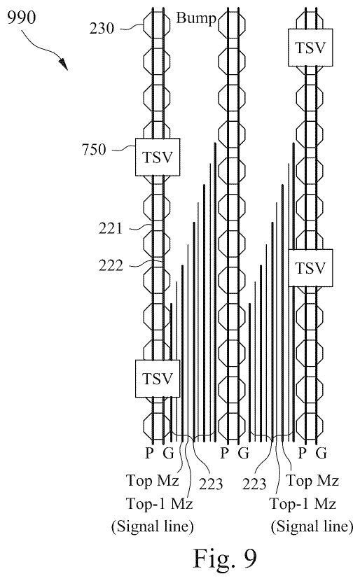

FIG. 9 illustrates a schematic diagram of a portion 990 of the interposer 120 shown in FIG. 8, in accordance with some embodiments. More specifically, the portion 990 shown in FIG. 9 may be an example configuration of a portion 890 shown in FIG. 8, and represents a column-wise layout, including the bump structures 230, the first interconnect structures 221 (e.g., power lines), the second interconnect structures 222 (e.g., ground lines), the third interconnect structures 223 (e.g., signal lines), and the TSVs 750. In some embodiments, as shown, the interposer 120 may include a P/G track per column. Each column in the portion 990 includes a P/G line (e.g., the first and second interconnect structures 221, 222), while signal lines (e.g., the third interconnect structures 223) are disposed therebetween. The signal lines may include first signal lines formed on a topmost metallization layer (e.g., an upper layer of the metallization layer 211) and second signal lines formed on a lower metallization layer (e.g., a lower layer of the metallization layer 211).

In this configuration, in which the P/G track is placed per column, each pair of the first and second interconnect structures 221, 222 may be formed along the column, under a corresponding column of the bump structures 230. The TSVs 750 may be placed, extending along the vertical direction, to deliver power, ground, or signals, with the bump structures 230 aligned above the first and second interconnect structures 221, 222 for direct coupling. This allows the semiconductor device (e.g., an LSI circuit) to connect more closely to VDD and/or VSS through the aligned TSVs 750 and the bump structures 230, reducing IR drop and enhancing power delivery efficiency.

In some embodiments, the increased number of P/G tracks (e.g., the first and second interconnect structures 221, 222) may lead to a more uniform distribution of power and ground, improving system stability and electrical symmetry across the semiconductor device. Since the number of P/G tracks increases, each track may use a thinner width, creating additional routing opportunities between adjacent P/G lines (e.g., the first and second interconnect structures 221, 222). This not only improves layout flexibility but also supports the placement of vertically stacked via structures (e.g., the second via structures 432 in FIG. 4) between the first and second interconnect structures 221, 222, enabling efficient signal routing from the bump structures 230 to internal interconnect layers. By leveraging the interstitial space for both horizontal signal traces and vertical vias, this improves area efficiency and enables more compact and scalable interposer architectures while maintaining robust PDN and signal integrity.

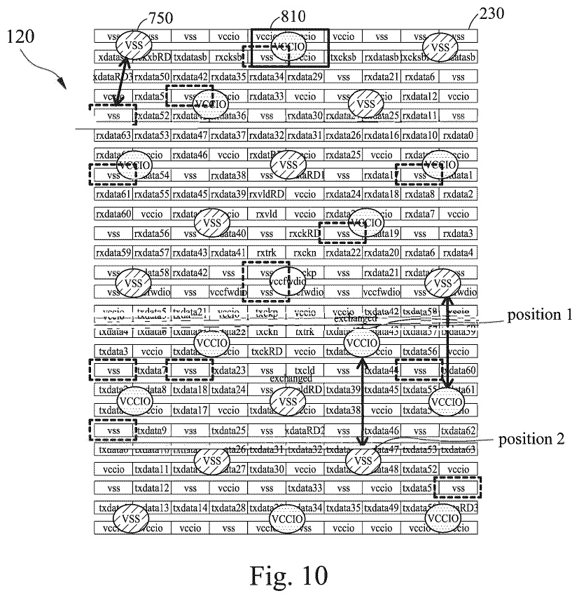

FIG. 10 illustrates a schematic diagram of an alternative example of the interposer 120, in accordance with some embodiments. More specifically, shown in FIG. 10 is a top, functional layout of the interposer 120 including the TSVs 750. In some embodiments, FIG. 10 shows a planar layout of the interposer 120 shown in FIG. 7.

As described herein, the bump-to-TSV alignment may be optimized to improve IR drop performance. Referring to FIG. 10, the interposer 120 may include a TSV distribution configured to reduce the number of “away” bumps, defined as bumps (e.g., among the bump structures 230) that are spaced a predetermined number of blocks (e.g., at two blocks) away from the corresponding TSV 750 (e.g., VSS or VCCIO). For example, the TSVs 750 may be positioned, adjusted, or otherwise formed, (e.g., exchanging a VCCIO TSV from position 2 to position 1 as opposed to the interposer 120 of FIG. 8) to better match the spatial location of corresponding bump voltages. This reduces the percentage of away bumps, while enabling improved local IR drop performance and more uniform power delivery across the interposer 120.

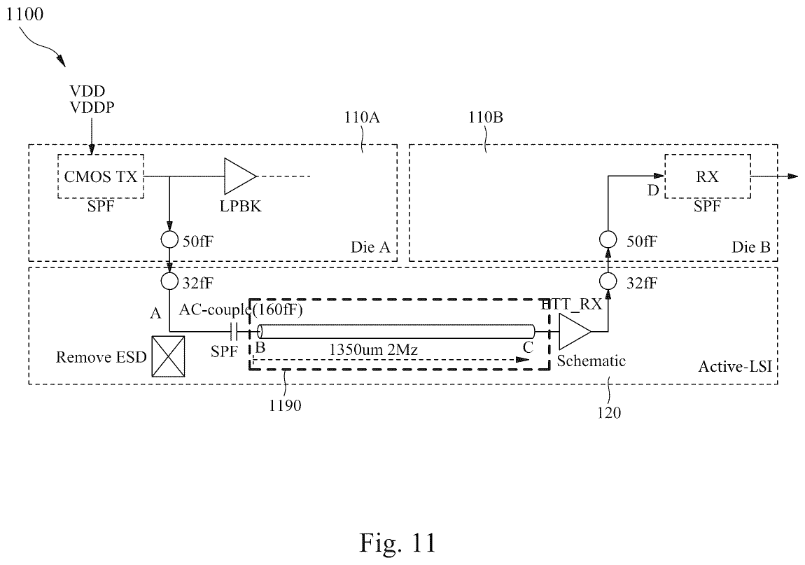

FIG. 11 illustrates a schematic diagram of an example of a semiconductor device 1100, in accordance with some embodiments. The semiconductor device 1100 may be similar to or incorporate features of the semiconductor device 100. For example, the semiconductor device 1100 includes an example of the die 110A, an example of the die 110B, and an example of the interposer 120. The interposer 120 of FIG. 11 may include a signal path segment 1190, which may be an example configuration of the portion 890 shown in FIG. 8. That is, the signal path from point B to point C in the interposer 120 may represent an instance of the detailed layout strategy shown above (e.g., FIGS. 8 and 9), incorporating power/ground routing and signal configurations.

In some embodiments, the die 110A shown in FIG. 11 may include a CMOS transmitter (CMOS TX) and a loopback (LPBK) path for transmitting test or functional signals. The CMOS TX may operate using one or more supply voltages (e.g., VDD, VDDP) and may include a source series terminated driver. The die 110A may include one or more capacitors (e.g., 50 fF, 32 fF) to adjust impedance or capacitance (e.g., the transition of the signal from the die 110A into the interposer 120). In some embodiments, the interposer 120 may include the signal path segment 1190, such as between the points B and C, which may include multiple interconnect layers (e.g., the first metallization layer 211). The signal path segment 1190 may be AC-coupled via a capacitor (e.g., 160 fF). In some embodiments, the interposer 120 may include or be coupled with a signal path filter (SPF). In some embodiments, the die 110B include a receiver (RX) configured to receive and process the signal transmitted from the die 110A. The receiver input may be preceded by a similar arrangement of input capacitors (e.g., 50 fF, 31 fF), ensuring proper impedance matching and timing adjustment. The signal may travel from point C in the interposer 120 to point D in the die 110B.

In the example of FIG. 11, the interposer 10 may be implemented as an Active-LSI, including circuit elements such as termination resistors or drivers (e.g., ET_RX) embedded within the silicon layers of the interposer 120. However, in some embodiments, the interposer 120 may be implemented as a passive LSI, in which case the same (or similar) layout and routing benefits may still be realized without including active circuit elements. The diagram thus represents a flexible implementation framework applicable to both active and passive interposer designs.

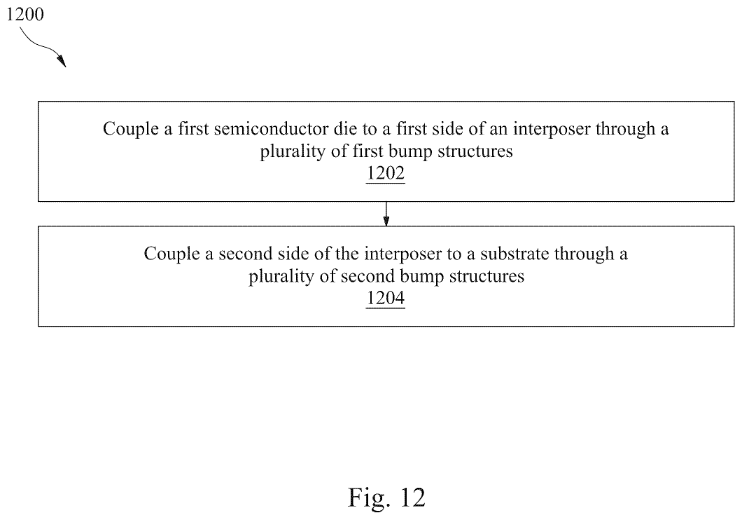

The figures and description above illustrate example architectural and layout features of the semiconductor device 100. To further describe non-limiting example implementation and manufacturing aspects of the disclosed structures, reference is now made to example package configurations and process flows as shown in FIGS. 12 to 19.

FIG. 12 includes a flowchart of a method 1200, in accordance with some embodiments. In some embodiments, the method 1200 may be associated with fabricating a semiconductor device (e.g., the semiconductor device 100). For example, at least some of the operations described in the method 1200 may result in the semiconductor devices illustrated above. The method 1200 is disclosed as a non-limiting example, and additional operations may be provided before, during, and after the method 1200 of FIG. 12. Further, some operations may only be described briefly herein, however, one skilled in the art will understand that the disclosed operations may be performed in conjunction with other disclosed methods disclosed herein, or generally known in the art. Further, the order of the disclosed operations is not intended to be limiting; certain operations may be performed in a different sequence, and still further operations may be sequenced with appropriate modifications thereto.

In brief summary, the method 1200 includes operation 1202 of coupling a first semiconductor die (e.g., the die 110A of FIG. 1) to a first side (e.g., a top) of an interposer (e.g., the interposer 120 of FIG. 2) through a plurality of first bump structures (e.g., the bump structures 230 of FIG. 2). The method 1200 may continue to operation 1204 of coupling a second side (e.g., a bottom) of the interposer to a substrate through a plurality of second bump structures (e.g., the TSV 750 of FIG. 7).

At operation 1202, a first semiconductor die (e.g., the die 110A of FIG. 1) may be coupled to a first side (e.g., a top) of an interposer (e.g., the interposer 120 of FIG. 2) through a plurality of first bump structures (e.g., the bump structures 230 of FIG. 2). At operation 1204, a second side of the interposer (e.g., the interposer 120 of FIG. 2) may be coupled to a substrate through a plurality of second bump structures (e.g., the TSV 750 of FIG. 7). In some embodiments, the interposer may include a plurality of first interconnect structures (e.g., the first interconnect structures 221) and a plurality of second interconnect structures (e.g., the second interconnect structures 222). The plurality of first interconnect structures may be configured to carry a first supply voltage (e.g., VDD). The plurality of second interconnect structures may be configured to carry a second supply voltage (e.g., VSS). Each of the plurality of first bump structures may be formed vertically above and laterally between a pair of a corresponding one of the plurality of first interconnect structures and a corresponding one of the plurality of second interconnect structures.

In some embodiments, the method 1200 may include coupling a second semiconductor die (e.g., the die 110B of FIG. 1) to the first side of the interposer through a plurality of third bump structures (e.g., the bump structures 230). Each of the plurality of third bump structures may be formed vertically above and laterally between a pair of a corresponding one of the plurality of first interconnect structures and a corresponding one of the plurality of second interconnect structures.

The method 1200 described above provide an example of how the interposer-based semiconductor devices disclosed herein may be fabricated. The following figures and description expand on this with package-level implementations and manufacturing system examples, including redistribution structures, bump interconnects, TSV integration, etc.

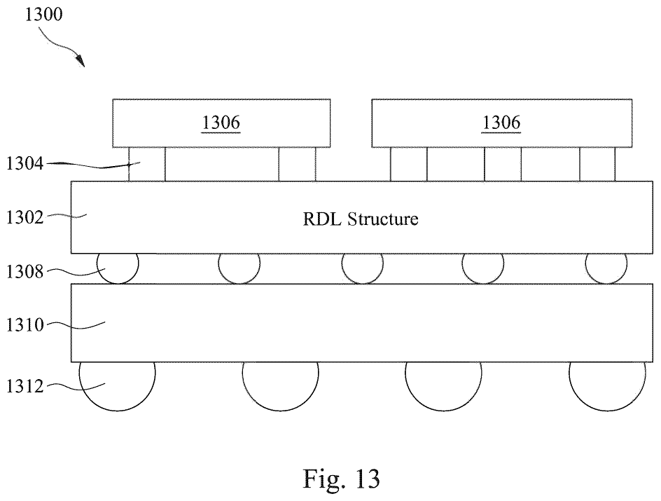

In FIG. 13, a package 1300 includes a redistribution structure 1302 having a number of the redistribution layers. The package 1300 includes a number of first connectors 1304 disposed on a first side of the redistribution structure 1302, and a number of second connectors 1308 disposed on a second, opposite side of the redistribution structure 1302. The first connectors 1304 are configured to couple the redistribution structure 1302 to a number of semiconductor dies 1306, and the second connectors 1308 are configured to couple the redistribution structure 1302 to a package substrate 1310. Further, on a side of the package substrate 1310 opposite to the side facing the redistribution structure 1302, the package 1300 includes a number of third connectors 1312. Such a package 1300 may sometimes be referred to as a Chip-on-Wafer-on-Substrate-Redistribution (CoWoS-R) integrated circuit.

In some embodiments, the first/second/third connectors 1304/1308/1312 may be solder balls, metal pillars, controlled collapse chip connection (C4) bumps, micro bumps, electroless nickel-electroless palladium-immersion gold technique (ENEPIG) formed bumps, combination thereof (e.g., a metal pillar having a solder ball attached thereof), or the like. The connectors 1304/1308/1312 may include a conductive material such as solder, copper, aluminum, gold, nickel, silver, palladium, tin, the like, or a combination thereof. In some embodiments, connectors 1304/1308/1312 comprise a eutectic material and may comprise a solder bump or a solder ball, as examples. The solder material may be, for example, lead-based and lead-free solders, such as Pb-Sn compositions for lead-based solder; lead-free solders including InSb; tin, silver, and copper (SAC) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 175, and SAC 405, as examples. Lead-free connectors such as solder balls may be formed from SnCu compounds as well, without the use of silver (Ag). Alternatively, lead-free solder connectors may include tin and silver, Sn-Ag, without the use of copper. The connectors 1304/1308/1312 may form a grid, such as a ball grid array (BGA). In some embodiments, a reflow process may be performed, giving the connectors 1304/1308/1312 a shape of a partial sphere in some embodiments. Alternatively, the connectors 1304/1308/1312 may comprise other shapes.

The connectors 1304/1308/1312 may also comprise non-spherical conductive connectors, for example. In some embodiments, the connectors 1304/1308/1312 comprise metal pillars (such as a copper pillar) formed by a sputtering, printing, electro plating, electroless plating, CVD, or the like, with or without a solder material thereon. The metal pillars may be solder free and have substantially vertical sidewalls or tapered sidewalls.

The connectors 1304/1308/1312 may also include an under bump metallization (UBM) formed and patterned over an uppermost metallization pattern in accordance with some embodiments, thereby forming an electrical connection with an uppermost metallization layer. The UBMs provides an electrical connection upon which an electrical connector, e.g., a solder ball/bump, a conductive pillar, or the like, may be placed. In an embodiment, the UBMs include a diffusion barrier layer, a seed layer, or a combination thereof. The diffusion barrier layer may include Ti, TiN, Ta, TaN, or combinations thereof. The seed layer may include copper or copper alloys. However, other metals, such as nickel, palladium, silver, gold, aluminum, combinations thereof, and multi-layers thereof, may also be included. In an embodiment, UBMs are formed using sputtering. In other embodiments, electro plating may be used.

The semiconductor dies 1306 may each include a main body, an interconnect region, and connectors. The main body may comprise any number of dies, substrates, transistors, active devices, passive devices, or the like. The interconnect region may provide a conductive pattern that allows a pin-out contact pattern for the main body. The connectors may be disposed on a side of each die, and may be used to physically and electrically connect the die to connectors 1304. The connectors may be electrically connected to the main body through the interconnect region. In various embodiments, the semiconductor dies 1306 may each be implemented as a logic die, a memory die, or a combination thereof. Example logic dies include Central Processing Units (CPUs), Application processors (APs), system on chips (SOCs), Application Specific Integrated Circuits (ASICs), or other types of logic dies including logic transistors therein. Example memory dies include Dynamic Random Access Memory (DRAM) dies, Static Random Access Memory (SRAM) dies, High-Bandwidth Memory (HBM) dies, Micro-Electro-Mechanical System (MEMS) dies, Hybrid Memory Cube (HMC) dies, or the like.

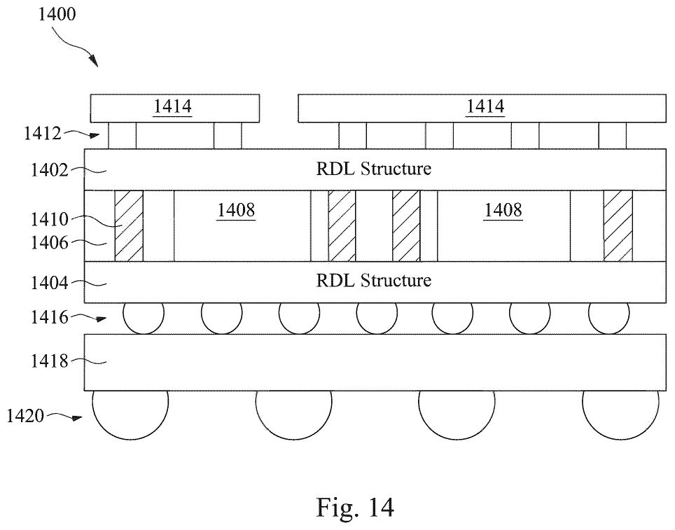

In FIG. 14, the package 1400 includes a first redistribution structure 1402 and a second redistribution structure 1404, each of which has a number of the redistribution layers. The package 1400 includes a molding material 1406 with the redistribution structures 1402 and 1404 disposed on its both sides, respectively. The molding material 1406 may include a molding compound, a molding underfill, an epoxy, or a resin. Within the molding material 1406, the package 1400 includes a number of interposers (sometimes referred to as Local Silicon Interconnection (LSI)) 1408 and a number of through vias 1410. The interposer 1408 can provide an increased number of electrical paths, connections, and the like, in a smaller area than would otherwise be possible. The package 1400 includes a number of first connectors 1412 disposed on a side of the first redistribution structure 1402 opposite to the side facing the molding material 1406, and a number of second connectors 1416 disposed on a side of the second redistribution structure 1404 opposite to the side facing the molding material 1406. The first connectors 1412 are configured to couple the first redistribution structure 1402 to a number of semiconductor dies 1414, and the second connectors 1416 are configured to couple the second redistribution structure 1404 to a package substrate 1418. Further, on a side of the package substrate 1418 opposite to the side facing the redistribution structure 1404, the package 1400 includes a number of third connectors 1420. The connectors 1412/1416/1420 may be implemented similarly to the connectors 1304/1308/1312 (FIG. 13), and thus, the discussions are not repeated. Also, the semiconductor dies 1414 may be implemented similarly to the semiconductor dies 1306 (FIG. 13), and thus, the discussion are not repeated. Such a package 1400 may sometimes be referred to as a Chip-on-Wafer-on-Substrate-LSI (CoWoS-L) integrated circuit.

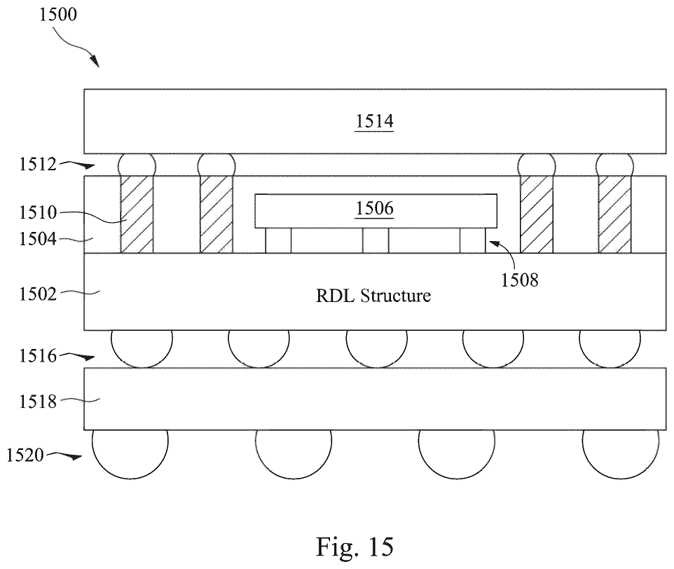

In FIG. 15, the package 1500 includes a redistribution structure 1502 having a number of the redistribution layers. The package 1500 includes a molding material 1504 disposed on a side of the redistribution structure 1502. The molding material 1504 may include a molding compound, a molding underfill, an epoxy, or a resin. Within the molding material 1504, the package 1500 includes a first semiconductor die 1506 coupled to the redistribution structure 1502 through a number of first connectors 1508. The package 1500 includes a number of through vias 1510 in the molding material 1504. The package 1500 includes a second semiconductor die 1514 coupled to the redistribution structure 1502 through a number of second connectors 1512, which are coupled to the through vias 1510. On a side of the redistribution structure 1502 opposite to the side facing the molding material 1504, the package 1500 includes a number of third connectors 1516 configured to couple the redistribution structure 1502 to a package substrate 1518. Further, on a side of the package substrate 1518 opposite to the side facing the redistribution structure 1502, the package 1500 includes a number of fourth connectors 1520. The connectors 1508/1512/1516/1520 may be implemented similarly to the connectors 1304/1308/1312 (FIG. 13), and thus, the discussions are not repeated. In some embodiments, the connectors 1508/1512/1516/1520 may not contain any C4 bumps. Also, the semiconductor dies 1506 and 1514 may be implemented as the logic die and the memory die, respectively, discussed above with respect to FIG. 13, and thus, the discussion are not repeated. Such a package 1500 may sometimes be referred to as an Integrated Fan-Out_Package-on-Package (InFo_PoP) integrated circuit.

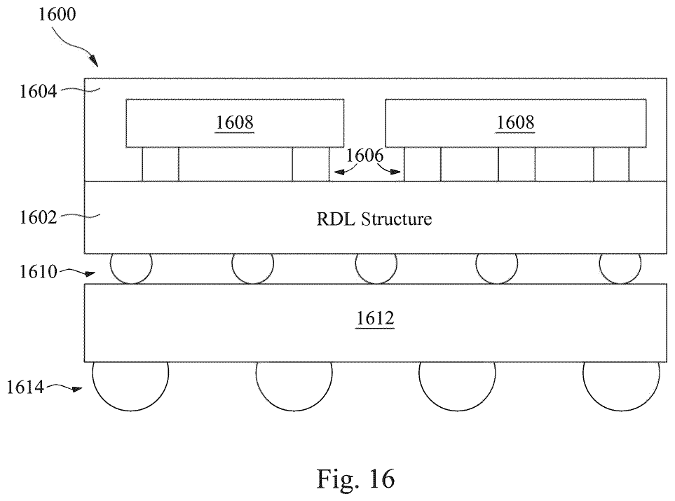

In FIG. 16, the package 1600 includes a redistribution structure 1602 having a number of the redistribution layers. The package 1600 includes a molding material 1604 disposed on a first side of the redistribution structure 1602. The molding material 1604 may include a molding compound, a molding underfill, an epoxy, or a resin. Within the molding material 1604, the package 1600 includes a number of first connectors 1606, which are configured to couple the redistribution structure 1602 to a number of semiconductor dies 1608 laterally spaced from one another. The package 1600 includes a number of second connectors 1610 disposed on a second, opposite side of the redistribution structure 1602. The second connectors 1610 are configured to couple the redistribution structure 1602 to a package substrate 1612. Further, on a side of the package substrate 1612 opposite to the side facing the redistribution structure 1602, the package 1600 includes a number of third connectors 1614. The connectors 1606/1610/1614 may be implemented similarly to the connectors 1304/1308/1312 (FIG. 13), and thus, the discussions are not repeated. Also, the semiconductor dies 1608 may be implemented similarly to the semiconductor dies 1306 (FIG. 13), and thus, the discussion are not repeated. Such a package 1600 may sometimes be referred to as an Integrated Fan-Out_on-Substrate (InFo_oS) integrated circuit.

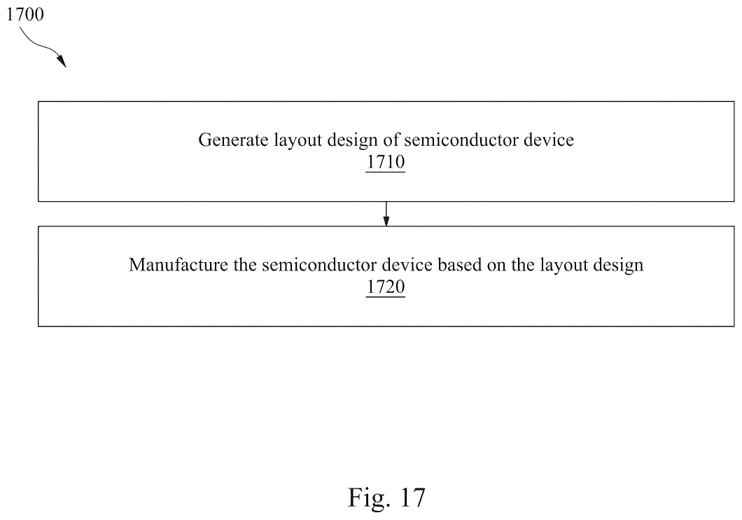

FIG. 17 is a flowchart of a method 1700 of forming or manufacturing a semiconductor device, in accordance with some embodiments. It is understood that additional operations may be performed before, during, and/or after the method 1700 depicted in FIG. 17. In some embodiments, the method 1700 is usable to form a semiconductor device, according to various layout designs as disclosed herein.

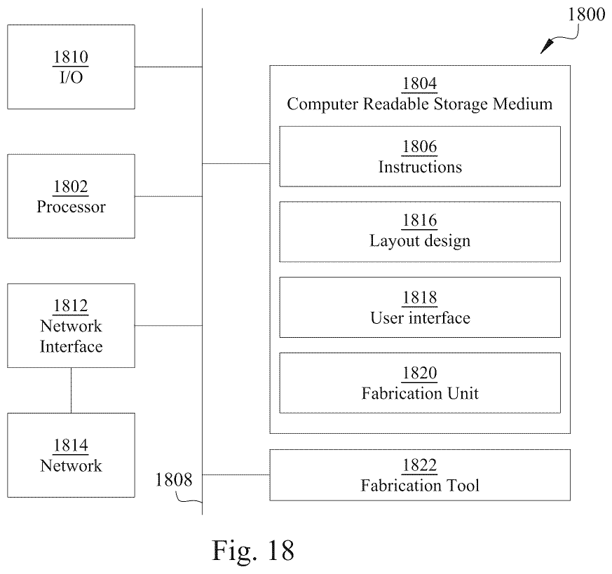

In operation 1710 of the method 1700, a layout design of a semiconductor device is generated. The operation 1710 is performed by a processing device (e.g., processor 1802 of FIG. 18) configured to execute instructions for generating a layout design. In one approach, the layout design is generated by placing layout designs of one or more standard cells through a user interface. In one approach, the layout design is automatically generated by a processor executing a synthesis tool that converts a logic design (e.g., Verilog) into a corresponding layout design. In some embodiments, the layout design is rendered in a graphic database system (GDSII) file format.

In operation 1720 of the method 1700, a semiconductor device (e.g., at least a portion of each of the packages 1300 to 1600) is manufactured based on the layout design. In some embodiments, the operation 1720 of the method 1700 includes manufacturing at least one mask based on the layout design, and manufacturing the a semiconductor device based on the at least one mask. A number of example manufacturing operations of the operation 1720 may be included in the method 1200 of FIG. 14 discussed above.

FIG. 18 is a schematic view of a system 1800 for designing and manufacturing an IC layout design, in accordance with some embodiments. The system 1800 generates or places one or more IC layout designs, as described herein. In some embodiments, the system 1800 manufactures one or more semiconductor devices based on the one or more IC layout designs, as described herein. The system 1800 includes a hardware processor 1802 and a non-transitory, computer readable storage medium 1804 encoded with, e.g., storing, the computer program code 1806, e.g., a set of executable instructions. The computer readable storage medium 1804 is configured for interfacing with manufacturing machines for producing the semiconductor device. The processor 1802 is electrically coupled to the computer readable storage medium 1804 by a bus 1808. The processor 1802 is also electrically coupled to an I/O interface 1810 by the bus 1808. A network interface 1812 is also electrically connected to the processor 1802 by the bus 1808. Network interface 1812 is connected to a network 1814, so that the processor 1802 and the computer readable storage medium 1804 are capable of connecting to external elements via network 1814. The processor 1802 is configured to execute the computer program code 1806 encoded in the computer readable storage medium 1804 in order to cause the system 1800 to be usable for performing a portion or all of the operations as described in method 1700.

In some embodiments, the processor 1802 is a central processing unit (CPU), a multi-processor, a distributed processing system, an application specific integrated circuit (ASIC), and/or a suitable processing unit.

In some embodiments, the computer readable storage medium 1804 is an electronic, magnetic, optical, electromagnetic, infrared, and/or a semiconductor system (or apparatus or device). For example, the computer readable storage medium 1804 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1804 includes a compact disk-read only memory (CD-ROM), a compact disk-read/write (CD-R/W), and/or a digital video disc (DVD).

In some embodiments, the storage medium 1804 stores the computer program code 1806 configured to cause the system 1800 to perform the method 1200. In some embodiments, the storage medium 1804 also stores information needed for performing method 1700 as well as information generated during performance of method 1700, such as layout design 1816, user interface 1818, fabrication unit 1820, and/or a set of executable instructions to perform the operation of method 1700.

In some embodiments, the storage medium 1804 stores instructions (e.g., the computer program code 1806) for interfacing with manufacturing machines. The instructions (e.g., the computer program code 1806) enable the processor 1802 to generate manufacturing instructions readable by the manufacturing machines to effectively implement the method 1700 during a manufacturing process.

The system 1800 includes the I/O interface 1810. The I/O interface 1810 is coupled to external circuitry. In some embodiments, the I/O interface 1810 includes a keyboard, keypad, mouse, trackball, trackpad, and/or cursor direction keys for communicating information and commands to the processor 1802.

The system 1800 also includes the network interface 1812 coupled to the processor 1802. The network interface 1812 allows the system 1800 to communicate with the network 1814, to which one or more other computer systems are connected. The network interface 1812 includes wireless network interfaces such as BLUETOOTH, WIFI, WIMAX, GPRS, or WCDMA; or wired network interface such as ETHERNET, USB, or IEEE-13154. In some embodiments, the method 1700 is implemented in two or more systems 1800, and information such as layout design, user interface and fabrication unit are exchanged between different systems 1800 by the network 1814.

The system 1800 is configured to receive information related to a layout design through the I/O interface 1810 or network interface 1812. The information is transferred to the processor 1802 by the bus 1808 to determine a layout design for producing an IC. The layout design is then stored in the computer readable medium 1804 as the layout design 1816. The system 1800 is configured to receive information related to a user interface through the I/O interface 1810 or network interface 1812. The information is stored in the computer readable medium 1804 as the user interface 1818. The system 1800 is configured to receive information related to a fabrication unit through the I/O interface 1810 or network interface 1812. The information is stored in the computer readable medium 1804 as the fabrication unit 1820. In some embodiments, the fabrication unit 1820 includes fabrication information utilized by the system 1800.

In some embodiments, the method 1700 is implemented as a standalone software application for execution by a processor. In some embodiments, the method 1700 is implemented as a software application that is a part of an additional software application. In some embodiments, the method 1700 is implemented as a plug-in to a software application. In some embodiments, the method 1700 is implemented as a software application that is a portion of an EDA tool. In some embodiments, the method 1700 is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, the method 1700 is implemented by a manufacturing device to manufacture an integrated circuit using a set of masks manufactured based on one or more layout designs generated by the system 1800. In some embodiments, the system 1800 includes a manufacturing device (e.g., fabrication tool 1822) to manufacture an integrated circuit using a set of masks manufactured based on one or more layout designs of the present disclosure. In some embodiments, the system 1800 of FIG. 18 generates layout designs of an IC that are smaller than other approaches. In some embodiments, the system 1800 of FIG. 18 generates layout designs of a semiconductor device that occupy less area than other approaches.

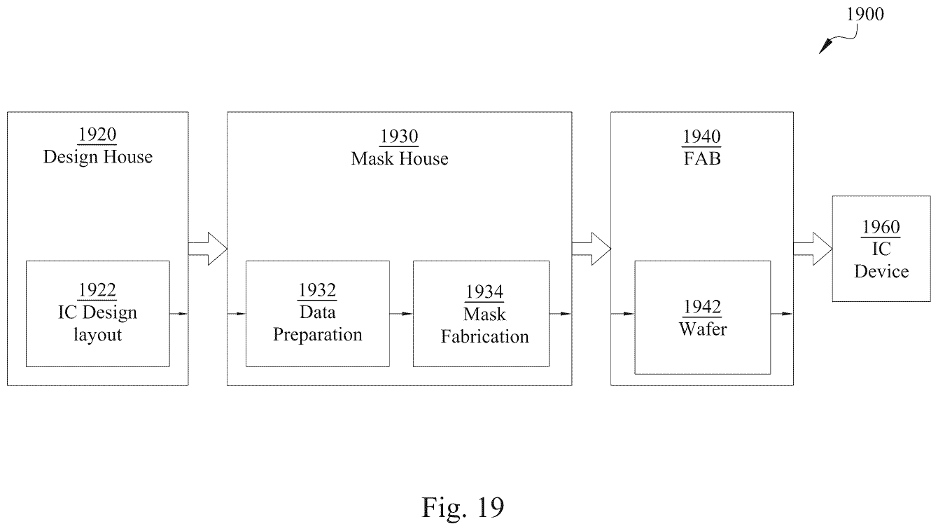

FIG. 19 is a block diagram of an integrated circuit (IC)/semiconductor device manufacturing system 1900, and an IC manufacturing flow associated therewith, in accordance with at least one embodiment of the present disclosure.

In FIG. 19, the IC manufacturing system 1900 includes entities, such as a design house 1920, a mask house 1930, and an IC manufacturer/fabricator (“fab”) 1940, that interact with one another in the design, development, and manufacturing cycles and/or services related to manufacturing an IC device (semiconductor device) 1960. The entities in system 1900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1920, mask house 1930, and IC fab 1940 is owned by a single company. In some embodiments, two or more of design house 1920, mask house 1930, and IC fab 1940 coexist in a common facility and use common resources.

The design house (or design team) 1920 generates an IC design layout 1922. The IC design layout 1922 includes various geometrical patterns designed for the IC device 1960. The geometrical patterns correspond to patterns of metal, oxide, or semiconductor layers that make up the various components of the IC device 1960 to be fabricated. The various layers combine to form various IC features. For example, a portion of the IC design layout 1922 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 1920 implements a proper design procedure to form the IC design layout 1922. The design procedure includes one or more of logic design, physical design or place and route. The IC design layout 1922 is presented in one or more data files having information of the geometrical patterns. For example, the IC design layout 1922 can be expressed in a GDSII file format or DFII file format.

The mask house 1930 includes mask data preparation 1932 and mask fabrication 1934. The mask house 1930 uses the IC design layout 1922 to manufacture one or more masks to be used for fabricating the various layers of the IC device 1960 according to the IC design layout 1922. The mask house 1930 performs the mask data preparation 1932, where the IC design layout 1922 is translated into a representative data file (“RDF”). The mask data preparation 1932 provides the RDF to the mask fabrication 1934. The mask fabrication 1934 includes a mask writer. A mask writer converts the RDF to an image on a substrate, such as a mask (reticle) or a semiconductor wafer. The design layout is manipulated by the mask data preparation 1932 to comply with particular characteristics of the mask writer and/or requirements of the IC fab 1940. In FIG. 19, the mask data preparation 1932 and mask fabrication 1934 are illustrated as separate elements. In some embodiments, the mask data preparation 1932 and mask fabrication 1934 can be collectively referred to as mask data preparation.

In some embodiments, the mask data preparation 1932 includes optical proximity correction (OPC) which uses lithography enhancement techniques to compensate for image errors, such as those that can arise from diffraction, interference, other process effects and the like. OPC adjusts the IC design layout 1922. In some embodiments, the mask data preparation 1932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 1934, which may undo part of the modifications performed by OPC in order to meet mask creation rules.

In some embodiments, the mask data preparation 1932 includes lithography process checking (LPC) that simulates processing that will be implemented by the IC fab 1940 to fabricate the IC device 1960. LPC simulates this processing based on the IC design layout 1922 to create a simulated manufactured device, such as the IC device 1960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 1922.

It should be understood that the above description of the mask data preparation 1932 has been simplified for the purposes of clarity. In some embodiments, the mask data preparation 1932 includes additional features such as a logic operation (LOP) to modify the IC design layout according to manufacturing rules. Additionally, the processes applied to the IC design layout 1922 during the mask data preparation 1932 may be executed in a variety of different orders.

After the mask data preparation 1932 and during mask fabrication 1934, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the photosensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 1934 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 1940 is an IC fabrication entity that includes one or more manufacturing facilities for the fabrication of a variety of different IC products. In some embodiments, the IC fab 1940 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 1940 uses the mask (or masks) fabricated by the mask house 1930 to fabricate the IC device 1960. Thus, the IC fab 1940 at least indirectly uses the IC design layout 1922 to fabricate the IC device 1960. In some embodiments, a semiconductor wafer 1642 is fabricated by the IC fab 1940 using the mask (or masks) to form the IC device 1960. The semiconductor wafer 1942 includes a silicon substrate or other proper substrate having material layers formed thereon. Semiconductor wafer further includes one or more of various doped regions, dielectric features, multilevel interconnects, and the like (formed at subsequent manufacturing steps).

The system 1900 is shown as having the design house 1920, mask house 1930, and IC fab 1940 as separate components or entities. However, it should be understood that one or more of the design house 1920, mask house 1930 or IC fab 1940 are part of the same component or entity.

In one aspect of the present disclosure, a semiconductor device is disclosed. The semiconductor device may include an interposer configured to connect a first semiconductor die to a second semiconductor die. The interposer may include a plurality of metallization layers and a plurality of bump structures disposed over a topmost one of the plurality of metallization layers. A first one of the plurality of metallization layers may include a plurality of first interconnect structures, a plurality of second interconnect structures, and a plurality of third interconnect structures. The plurality of first interconnect structures may be configured to carry a first supply voltage. The plurality of second interconnect structures may be configured to carry a second supply voltage. The plurality of third interconnect structures may each be configured as a signal line. Each of the plurality of bump structures may be formed directly above a pair of a corresponding one of the plurality of first interconnect structures and a corresponding one of the plurality of second interconnect structures.

In another aspect of the present disclosure, a semiconductor device is disclosed. The semiconductor device may include a first semiconductor die, a second semiconductor die, an interposer, and a substrate bonded to the interposer. The interposer may be bonded to the first and second semiconductor dies. The interposer may be configured to connect the first semiconductor die to the second semiconductor die. The interposer may include a plurality of bump structures, a plurality of first interconnect structures, and a plurality of second interconnect structures. The plurality of first interconnect structures may be configured to carry a first supply voltage. The plurality of second interconnect structures may be configured to carry a second supply voltage. Each of the plurality of bump structures may be formed vertically above and laterally between a pair of a corresponding one of the plurality of first interconnect structures and a corresponding one of the plurality of second interconnect structures.

In another aspect of the present disclosure, a method is disclosed. The method may include coupling a first semiconductor die to a first side of an interposer through a plurality of first bump structures. The method may include coupling a second side of the interposer to a substrate through a plurality of second bump structures. The interposer may include a plurality of first interconnect structures and a plurality of second interconnect structures. The plurality of first interconnect structures may be configured to carry a first supply voltage. The plurality of second interconnect structures may be configured to carry a second supply voltage. Each of the plurality of first bump structures may be formed vertically above and laterally between a pair of a corresponding one of the plurality of first interconnect structures and a corresponding one of the plurality of second interconnect structures.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
an interposer configured to connect a first semiconductor die to a second semiconductor die, the interposer comprising:
a plurality of metallization layers; and
a plurality of bump structures disposed over a topmost one of the plurality of metallization layers;
wherein a first one of the plurality of metallization layers comprises a plurality of first interconnect structures, a plurality of second interconnect structures, and a plurality of third interconnect structures, the plurality of first interconnect structures configured to carry a first supply voltage, the plurality of second interconnect structures configured to carry a second supply voltage, the plurality of third interconnect structures each configured as a signal line; and
wherein each of the plurality of bump structures is formed directly above a pair of a corresponding one of the plurality of first interconnect structures and a corresponding one of the plurality of second interconnect structures.

2. The semiconductor device of claim 1, wherein the first supply voltage is VDD, and the second supply voltage is VSS.

3. The semiconductor device of claim 1, wherein the interposer further comprises a plurality of via structures, a first one of which and a second one of which are configured to connect each of the plurality of bump structures to a corresponding one of the plurality of third interconnect structures.

4. The semiconductor device of claim 3, wherein the second via structure is disposed vertically beneath the first via structure.

5. The semiconductor device of claim 4, wherein the second via structure is laterally interposed between the pair of the corresponding first interconnect structure and the corresponding second interconnect structure.

6. The semiconductor device of claim 4, wherein the first via structure has a first width and the second via structure has a second width, and wherein the first width is greater than the second width.

7. The semiconductor device of claim 1, wherein the plurality of first interconnect structures, the plurality of second interconnect structures, and the plurality of third interconnect structures extend along a first lateral direction.

8. The semiconductor device of claim 7, wherein the interposer further comprises a plurality of fourth interconnect structures extending along a second lateral direction perpendicular to the first lateral direction, and wherein each of the bump structures is coupled to a corresponding one of the third interconnect structures through one or more via structures and a corresponding one of the plurality of fourth interconnect structures.

9. The semiconductor device of claim 8, wherein the fourth interconnect structures are disposed in a second one of the plurality of metallization layers.

10. The semiconductor device of claim 9, wherein the second metallization layer is disposed below the first metallization layer, with the bump structures disposed above the first metallization layer.

11. The semiconductor device of claim 1, wherein the first semiconductor die and the second semiconductor die are disposed above and bonded to the interposer, and the semiconductor device further comprises a substrate disposed below the interposer and bonded to the interposer.

12. A semiconductor device, comprising:
a first semiconductor die and a second semiconductor die;
an interposer bonded to the first and second semiconductor dies, and configured to connect the first semiconductor die to the second semiconductor die; and
a substrate bonded to the interposer;
wherein the interposer comprises a plurality of bump structures, a plurality of first interconnect structures, and a plurality of second interconnect structures, the plurality of first interconnect structures configured to carry a first supply voltage, the plurality of second interconnect structures configured to carry a second supply voltage; and
wherein each of the plurality of bump structures is formed vertically above and laterally between a pair of a corresponding one of the plurality of first interconnect structures and a corresponding one of the plurality of second interconnect structures.

13. The semiconductor device of claim 12, wherein the first supply voltage is VDD, and the second supply voltage is VSS.

14. The semiconductor device of claim 12, wherein the interposer further comprises a plurality of via structures, a first one of which and a second one of which are configured to connect each of the plurality of bump structures to a corresponding one of a plurality of third interconnect structures.

15. The semiconductor device of claim 14, wherein the first interconnect structures, the second interconnect structures, and the third interconnect structures are disposed in a same metallization layer.

16. The semiconductor device of claim 14, wherein the second via structure is disposed vertically beneath the first via structure.

17. The semiconductor device of claim 16, wherein the first via structure has a first width and the second via structure has a second width, and wherein the first width is greater than the second width.

18. The semiconductor device of claim 16, wherein the second via structure extends through a space laterally interposed between the corresponding first interconnect structure and the corresponding second interconnect structure.

19. A method, comprising:
coupling a first semiconductor die to a first side of an interposer through a plurality of first bump structures;
coupling a second side of the interposer to a substrate through a plurality of second bump structures;
wherein the interposer comprises a plurality of first interconnect structures and a plurality of second interconnect structures, the plurality of first interconnect structures configured to carry a first supply voltage, the plurality of second interconnect structures configured to carry a second supply voltage; and
wherein each of the plurality of first bump structures is formed vertically above and laterally between a pair of a corresponding one of the plurality of first interconnect structures and a corresponding one of the plurality of second interconnect structures.

20. The method of claim 19, further comprising:
coupling a second semiconductor die to the first side of the interposer through a plurality of third bump structures;
wherein each of the plurality of third bump structures is formed vertically above and laterally between a pair of a corresponding one of the plurality of first interconnect structures and a corresponding one of the plurality of second interconnect structures.
